(19) United States
(12) Patent Application Publication
(10) Pub. No.: US 2013/0284418 A1
(43) Pub. Date: Oct. 31, 2013

(54) METHOD FOR CONTROLLING FANS OF ELECTRONIC DEVICE

(71) Applicants: HONG FU JIN PRECISION INDUSTRY (SHENZHEN) CO.,, Shenzhen (CN); HON HAI PRECISION INDUSTRY CO., LTD., New Taipei (TW)

(72) Inventors: LIAN-MING GUO, Shenzhen (CN); XIAO HU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/688,449

(22) Filed: Nov. 29, 2012

(30) Foreign Application Priority Data
Apr. 27, 2012 (CN) 201210127517.8

(51) Int. Cl. H05K 7/20

(52) U.S. Cl. CPC H05K 7/20209
USPC 165/247; 165/11.1

(57) ABSTRACT

A control method for fan includes the following steps: a temperature value for a heat element is detected by a heat detecting unit, and the temperature value is transmitted to an infrastructure management module; a fan input control signal is calculated according to the temperature value; the fan input control signal is transmitted to a fan board through the heat detecting unit; an input speed information is input to the fan for dissipating the heat element by the fan board according to the fan input control signal; an output speed information of the fan is received; and determining whether the fan works as predefined by the fan board according to the output speed information and the input speed information.

### CROSS-REFERENCE TO RELATED APPLICATIONS

This application claims all benefits accruing under 35 U.S.C. §119 from China Patent Application No. 201210127517.8, filed on Apr. 27, 2012, in the China Intellectual Property Office, the contents of which are hereby incorporated by reference. Relevant subject matter is disclosed in co-pending U.S. Patent Applications entitled “FAN CONTROL SYSTEM,” Attorney Docket Number US45162, U.S. application Ser. No. ______, filed on ______; co-pending U.S. Patent Applications entitled “CONTROL METHOD AND SYSTEM FOR FANS OF ELECTRONIC DEVICE”, Attorney Docket Number US43875, U.S. application Ser. No. ______, filed on ______.

### BACKGROUND

1. Technical Field

The disclosure generally relates to a method for controlling fans of an electronic device.

2. Description of Related Art

A plurality of heat sinks is used in traditional electronic devices for absorbing heat from electronic elements. Fans are used for dissipating heat from heat sink. In these electronic devices, rotation speeds of the fans cannot be well adjusted according to the temperatures of the electronic elements. In addition, an input controlling rotation speed of the fan may not be in accordance with an output rotation speed of the fan. The supposed dissipating effect of the heat sink may be different from the actually dissipating effect in conventional electronic device.

There is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block view of a fan control system in one embodiment.

FIG. 2 is a flowchart of a control method for fans in one embodiment.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

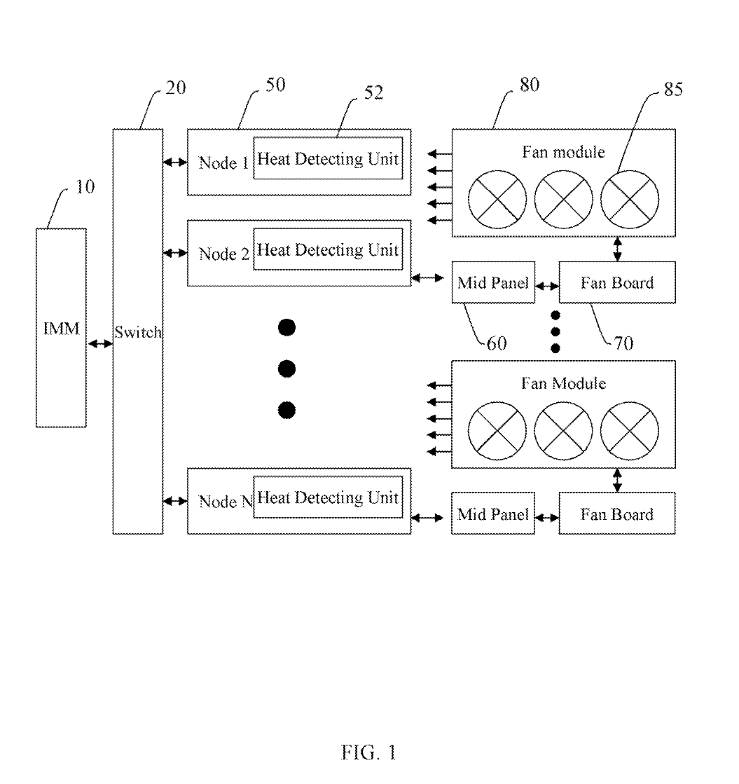

FIG. 1 shows that in one embodiment, a fan control system may be used in data center container for dissipating heat from a plurality of electronic devices. The fan control system includes an infrastructure management module (IMM) 10, a switch 20, a plurality of nodes 50, a plurality of mid panels 60, a plurality of fan boards 70, and a plurality of fan modules 80.

The IMM 10 may be a remote processor relative to the plurality of nodes 50. The IMM 10 is connected to the switch 20. The switch 20 is connected to the plurality of nodes 50. The plurality of nodes 50 are connected to a local area network through the switch 20. The plurality of mid panels 60 is connected to the plurality of nodes 50. The plurality of mid panels 60 is connected to the plurality of fan boards 70.

In one embodiment, each node 50 may be a heat element, such as a server. The plurality of nodes 50 may include N nodes. Each node 50 includes a heat detecting unit 52. The heat detecting unit 52 includes a plurality of heat sensors for detecting temperatures of a plurality of heat generating components inside each node 50. The heat detecting units 52 can receive a maximum or an average temperature value from the plurality of heat sensors.

Each mid panel 60 can be connected to one or more nodes 50. For example, each mid panel 60 is connected to three nodes 50. The plurality of mid panels 60 can be connected to the plurality of nodes 50 through inter-integrated circuit (I2C) bus.

Each mid panel 60 is connected to each fan board 70. The fan board 70 is used to control the fan modules 80. Each fan board 70 may include an indicator light for indicating whether the fan module 80 fails. The fan board 70 is connected to the mid panel 60 through the I2C bus.

In one embodiment, the plurality of fan modules 80 is located at a side of the plurality of nodes 50. Each fan module 80 may include a plurality of fans 85. Each fan 85 includes a rotating speed sensing module. The fans 85 can be controlled by the fan board 70. The fan module 80 is connected to the fan board 70 through the I2C bus.

In one embodiment, the fans 85 connected to one of the mid panels 60 may be the same ones corresponding to the nodes 50 connected to the mid panels 60.

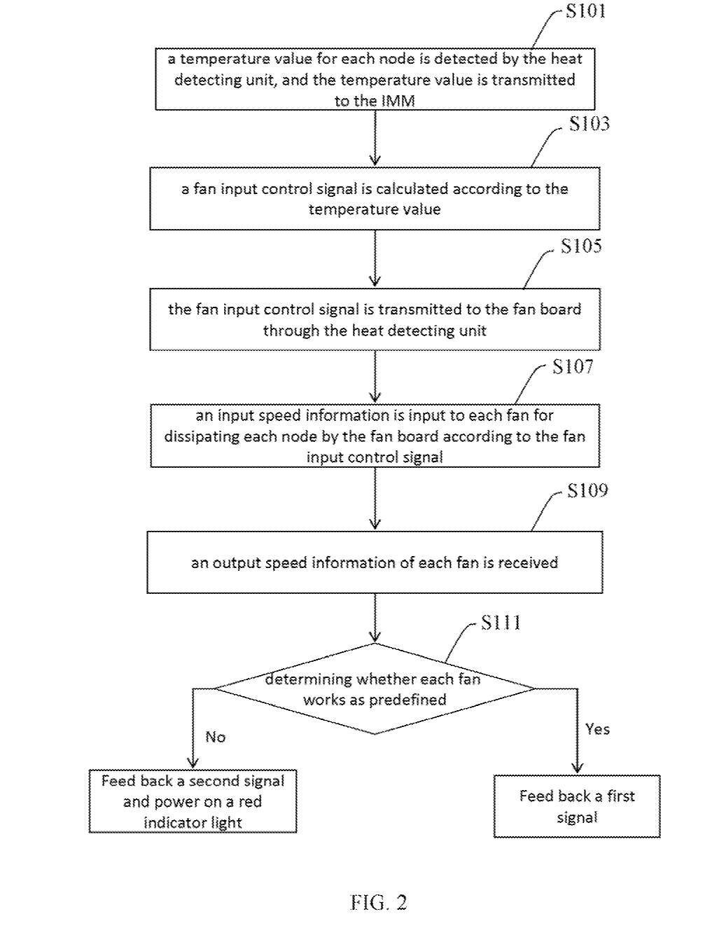

FIG. 2 shows that in one embodiment, a control method for fans includes the following blocks:

S101: a temperature value for each node 50 is detected by the heat detecting unit 52, and the temperature value is transmitted to the IMM 10.

S103: a fan input control signal is calculated according to the temperature value.

S105: the fan input control signal is transmitted to the fan board 70 through the heat detecting unit 52. In detail, the fan input control signal is transmitted to the heat detecting unit 52 from the IMM 10. The fan input control signal is transmitted to the mid panel 60. The fan input control signal is transmitted to the fan board 70 from the mid panel 60.

S107: an input speed information is input to each fan 85 for dissipating each node 50 by the fan board 70 according to the fan input control signal. The input speed information may include a percentage value relative to an original speed value.

S109: an output speed information of each fan 85 is received. The output speed information may include a speed value. The fan board 70 may select a largest speed value from received input speed information, and input the largest input speed information to each fan 85.

S111: determining whether each fan 85 works as predefined by the fan board 70 according to the output speed information and the input speed information. A safe range value is stored in the fan board 70, and the fan board 70 may determine whether a difference between an output speed value of each fan 85 and an input speed value exceeds the safe range value. A first signal is feed back to the IMM 10 through each heat detecting unit 52 from the fan board 70, if each fan 85 works as predefined. A second signal is feed back to the IMM 10 through each heat detecting unit 52, if each fan 85 does not work as predefined. A red indicator light on the fan board 70 is powered, if the fan 85 does not work as predefined.

It is also understood, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A control method for fan comprising:
detecting a temperature value for a heat element by a heat detecting unit, and transmitting the temperature value to an infrastructure management module (IMM);
calculating a fan input control signal according to the temperature value;
transmitting the fan input control signal to a fan board through the heat detecting unit;
inputting an input speed information to the fan for dissipating the heat element by the fan board according to the fan input control signal;
receiving an output speed information of the fan; and
determining whether the fan works as predefined by the fan board according to the output speed information and the input speed information.

2. The control method of claim 1, further comprising:
feeding back a first signal to the IMM through the heat detecting unit, when the fan works as predefined; and
feeding back a second signal to the IMM through the heat detecting unit, when the fan does not work as predefined.

3. The control method of claim 1, further comprising lighting on a red indicator light of the fan board, when the fan does not work as predefined.

4. The control method of claim 1, wherein the IMM is configured to connect a plurality of heat detecting units through a switch.

5. The control method of claim 1, wherein the heat element is a server, and the heat detecting unit comprises at least one heat sensor located inside the server.

6. The control method of claim 1, wherein the output speed information comprises a percentage value relative to an original speed value, and the output speed information comprises a speed value.

7. The control method of claim 1, wherein transmitting the fan input control signal to the fan board through the heat detecting unit further comprises:
transmitting the fan input control signal to the heat detecting unit from the IMM;
transmitting the fan input control signal to a mid panel; and
transmitting the fan input control signal to the fan board from the mid panel.

8. The control method of claim 7, wherein the mid panel is connected to a plurality of heat detecting units, and the mid panel is connected to the fan board.

9. The control method of claim 8, further comprising the fan board selecting a largest speed value from received input speed information, and inputting the largest input speed information to the fan.

10. The control method of claim 1, wherein a safe range value is stored in the fan board, and the fan board determines whether a difference between an output speed value of the fan and an input speed value exceeds the safe range value.

11. A control method for fans comprising:
detecting a plurality of temperature values for a plurality of heat elements by a plurality of heat detecting units attached to the plurality of heat elements, and transmitting the plurality of temperature values to a remote processor;
calculating a plurality of fan input control signals according to the plurality of temperature values;
transmitting the plurality of fan input control signals to a fan board through the plurality of heat detecting units;
inputting an input speed information to each fan for dissipating each of the plurality of heat elements by the fan board according to each of the plurality of fan input control signals;
receiving an output speed information of each fan by the fan board; and
determining whether each fan works as predefined by the fan board according to each the output speed information and each input speed information.

12. The control method of claim 11, further comprising:
feeding back a first signal to the remote processor through each heat detecting unit from the fan board, when each fan works as predefined; and
feeding back a second signal to the remote processor through each heat detecting unit, when each fan does not work as predefined.

13. The control method of claim 11, further comprising lighting on a red indicator light on the fan board, when one of the fans does not work as predefined.

14. The control method of claim 11, wherein the remote processor is configured to connect the plurality of heat detecting units through a switch.

15. The control method of claim 11, wherein each heat element is a server, and each heat detecting unit comprises at least one heat sensor located inside each server.

16. The control method of claim 11, wherein each output speed information comprises a percentage value relative to an original speed value, and each output speed information comprises a speed value.

17. The control method of claim 11, wherein transmitting the plurality of fan input control signals to the fan board through the plurality of heat detecting units further comprises:
transmitting the plurality of fan input control signals to the plurality of heat detecting units from the remote processor;
transmitting the plurality of fan input control signals to a mid panel; and transmitting the plurality of fan input control signals to the fan board from the mid panel.

18. The control method of claim 17, wherein the mid panel is connected to the plurality of heat detecting units, and the mid panel is connected to the fan board.

19. The control method of claim 18, further comprising the fan board selecting a largest speed value from received input speed information, and inputting the largest input speed information to the plurality of fans.

20. The control method of claim 11, wherein a safe range value is stored in the fan board, and the fan board determines whether a difference between an output speed value of the fan and an input speed value exceeds the safe range value.
